(19) United States
(12) Patent Application Publication
(10) Pub. No.: US 2012/0233520 A1
(43) Pub. Date: Sep. 13, 2012

(54) Information Processing Apparatus and Information Processing Method

(76) Inventor: Mitsutoshi Aoyagi, Kawagoe-shi (JP)

(21) Appl. No.: 13/482,863

(22) Filed: May 29, 2012

Related U.S. Application Data
(63) Continuation of application No. 12/969,410, filed on Dec. 15, 2010.

(30) Foreign Application Priority Data
Mar. 30, 2010 (JP) 2010-077275

(51) Int. Cl. H03M 13/29; G06F 12/02; G06F 11/10

(52) U.S. Cl. 714/755; 714/E11.035

(57) ABSTRACT

According to one embodiment, there is provided an information processing apparatus including: a flash memory storing data and a first error correcting code at a physical storage area thereof, the physical storage area including a plurality of blocks, each block including a plurality of columns; a first error correcting portion configured to perform, when there is an erroneous part in the data physically read from the flash memory, a first error correction based on the first error correcting code physically read from the flash memory to thereby correct the erroneous part; and a second error correcting portion configured to perform, when the erroneous part is not corrected through the first error correction, a second error correction based on a second error correcting code obtained from the read data to thereby correct the erroneous part.

### CROSS-REFERENCE TO RELATED APPLICATION(S)

This application is a continuation application of U.S. patent application Ser. No. 12/969,410 filed Dec. 15, 2010, now abandoned, which is based upon and claims the benefit of priority from Japanese Patent Application No. 2010-077275, filed on Mar. 30, 2010, the entire contents of which are incorporated herein by reference.

### FIELD

Embodiments described herein relate generally to an information processing apparatus and information processing method, which write and read data to and from a flash memory, e.g., a flash read-only memory (ROM) and which perform processing.

### BACKGROUND

With recent improvements in microfabrication technology, flash memories (e.g., flash ROMs) have increasingly been miniaturized, and inexpensive large-capacity flash memories have been manufacturable.

On the other hand, the reliability of data retention has been degraded. Sometimes, data written to a flash memory is corrupted due to some cause and cannot correctly be read therefrom.

If the data of a boot program for starting an apparatus (system) is corrupted, the apparatus (system) itself may not start. For example, in a case of a home-use apparatus (such as a digital television receiver), when the start-up fails, nothing is displayed on the screen of the home-use apparatus, and it is difficult for a user to deal with such a situation.

For example, JP-2005-215824-A proposes a technique to correctly read data stored in a flash memory, which had not correctly been read therefrom. That is, a boot program is previously stored in each of plural different blocks. Then, an ECC (error correcting code)-based determination is performed on data read from one of the blocks. If the block is determined as a defective block, the boot program is read from another one of the blocks. Thus, data determined not to be defective is output to a central processing unit (CPU).

However, according to the above technique, if it is determined, based on ECC, that plural blocks, to each of which a boot program is written, are defective, correct data cannot be sent to the CPU. Consequently, if each of such blocks is defective, the system cannot be started.

### BRIEF DESCRIPTION OF THE DRAWINGS

A general architecture that implements the various feature of the present invention will now be described with reference to the drawings. The drawings and the associated descriptions are provided to illustrate embodiments of the present invention and not to limit the scope of the present invention.

FIG. 1 illustrates the configuration of a television (TV) apparatus according to an embodiment.

FIG. 2 illustrates the configuration of data to be written to a flash ROM.

FIG. 3 schematically illustrates an ECC generated corresponding to a storage area of the flash ROM.

FIG. 4 is a flowchart illustrating a start-up operation of the TV apparatus.

FIG. 5 is a flowchart illustrating an ECC correction operation during the start-up operation.

### DETAILED DESCRIPTION

In general, according to one embodiment, there is provided an information processing apparatus including: a flash memory storing data and a first error correcting code at a physical storage area thereof, the physical storage area including a plurality of blocks, each block including a plurality of columns; a first error correcting portion configured to perform, when there is an erroneous part in the data physically read from the flash memory, a first error correction based on the first error correcting code physically read from the flash memory to thereby correct the erroneous part; and a second error correcting portion configured to perform, when the erroneous part is not corrected through the first error correction, a second error correction based on a second error correcting code obtained from the read data to thereby correct the erroneous part.

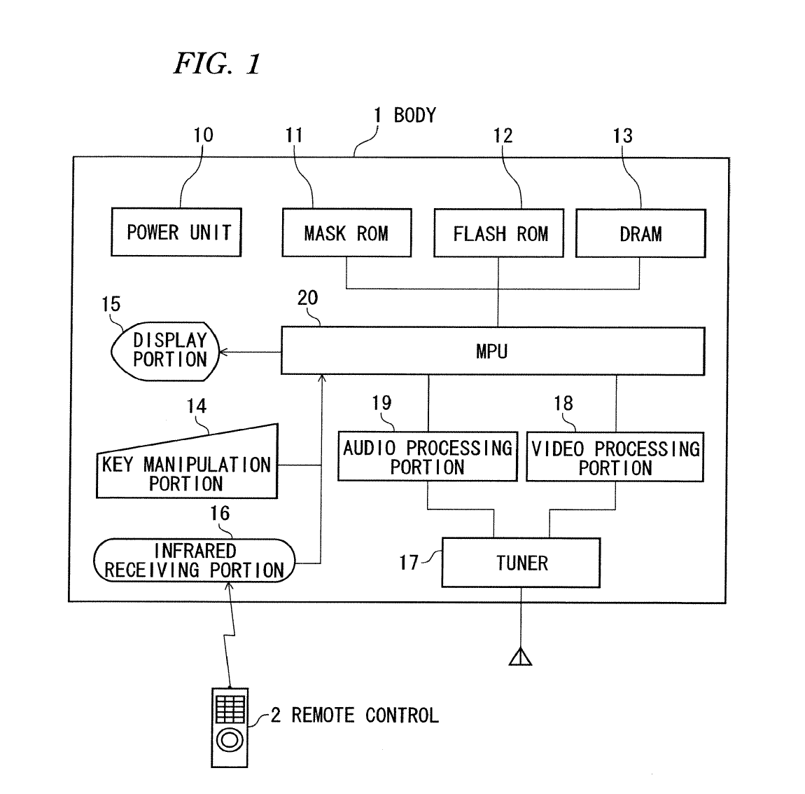

Hereinafter, a television receiving apparatus (hereunder referred to as a “TV apparatus”) is exemplified as an embodiment of an information processing apparatus. FIG. 1 illustrates the configuration of a TV apparatus body 1 (hereinafter referred to as a “TV body 1”).

As illustrated in FIG. 1, in a TV apparatus according to this embodiment, a TV body 1 includes a power unit 10, a mask ROM 11, a flash ROM 12, a dynamic random access memory 13 (hereinafter referred to as a “DRAM 13”), a key manipulation portion 14, a display portion 15 configured to display an image, an infrared receiving portion 16, a tuner 17, a video processing portion 18, an audio processing portion 19, a micro-processing unit (MPU) 20 and the like.

The key manipulation portion 14 includes, e.g., a power supply key, a sound volume up-down key, a channel manipulation key, a direction key, a menu key, and the like.

The power unit 10 performs, when the power supply key of the key manipulation portion 14 is turned on, alternating-current/direct-current (AC/DC) conversion or reduction of an AC voltage of 100 volts (V) supplied from a commercial power supply. Thus, the power unit 10 supplies a power to each portion in the TV body 1.

The mask ROM 11 is configured such that data written thereto cannot be rewritten. The mask ROM 11 stores a boot program to be read by the MPU 20 when powered on, and various data, such as initial setting data, which is not rewritten.

The flash ROM 12 is a nonvolatile memory configured such that data written thereto can be rewritten. Although data once stored in the flash ROM is not erased even when no electric-current is applied thereto, the recent miniaturized flash ROM 12 still involves factors destabilizing the data retention performance thereof. When the apparatus starts, the program read by the MPU 20 is once stored in the flash ROM 12 in units of a relatively large amount of data. The unit of a relatively large amount of program data is an amount of data (i.e., about 16 Kbytes) that can be written to the storage area of the flash ROM 12 at a time. That is, the flash ROM 12 has a physical storage area to which data can be stored in units of blocks each configured by plural columns as one unit.

The DRAM 13 is a high-speed memory that retains data while a power for data retention is supplied. Program data, such as boot programs and initial setting data, read from the flash ROM 12 by the MPU 20 in executable units is written to the DRAM 13. Thus, processing is executed.

The infrared receiving portion 16 receives a start-up signal sent from a remote controller 2 (hereunder referred to as a “remote control 2”) or a start-up signal generated when the power supply key is turned on, and sent from the key manipulation portion 14 provided in the TV body 1 (the apparatus body).

The tuner 17 receives a TV broadcast program input from an antenna and outputs the video data of the received program to the video processing portion 18. The tuner 17 also outputs the audio data of the received program to the audio processing portion 19. The tuner 17 has at least one of a digital tuner and an analog tuner. Plural digital tuners and/or plural analog tuners can be mounted in the apparatus.

The video processing portion 18 reproduces digital video data or analog video signals input from the tuner 17 as an image to be displayed in the display portion 15.

The audio processing portion 19 reproduces digital audio data or analog audio signals input from the tuner 17 as sounds to be output from a speaker (not shown).

The MPU 20 loads, into the DRAM 13, a boot program and initial setting data read from the flash ROM 12. Then, the MPU 20 performs error check on data of every block using a check sum read from a physical storage location in the storage area of the flash ROM 12. If the data is correct, the MPU 20 performs a start-up process. If it is found, as a result of the error check, that a part or all of the checked data of every block is not correct, the MPU 20 corrects an erroneous part of the data by performing data error correction (first error correction) using an error correcting code (ECC, hereinafter referred to as a “first ECC”, stored at a physical storage location on a memory) read from a physical storage location in the flash ROM 12. The combination of the error check and the error correction is referred to as “error correction processing”.

When the erroneous part cannot be corrected by the first error correction, the MPU 20 corrects (repairs) program data itself read from the flash ROM 12 using an ECC (an ECC on software, hereinafter referred to as a “second ECC”) included in the program data. That is, the MPU 20 performs second error correction. Then, the MPU 20 overwrites data of the erroneous-part in the flash ROM 12 by replacing the data of the erroneous-part with correct data (i.e., the correct data is written back to the storage location of the erroneous part). Thereafter, the MPU 20 reads the program data stored in the flash ROM 12 again. Then, the MPU 20 executes the read program. That is, the MPU 20 performs the start-up process.

That is, the MPU 20 functions as a first error correcting portion which reads data from a physical storage location in the flash ROM 12 and which corrects an erroneous part of the read data by performing the first error correction based on the first ECC read from a physical storage location in the storage area.

The MPU 20 also functions as a second error correcting portion which corrects an erroneous part by performing, when the erroneous part cannot be corrected as a result of the first error correction, the second error correction based on the second ECC given to (included in) the data read from the flash ROM 12.

In addition, the MPU 20 also functions as a program executing portion which reads, after writing back to the flash ROM 12 the data whose erroneous part is corrected, the data from the flash ROM 12 to the DRAM 13 and which executes the program.

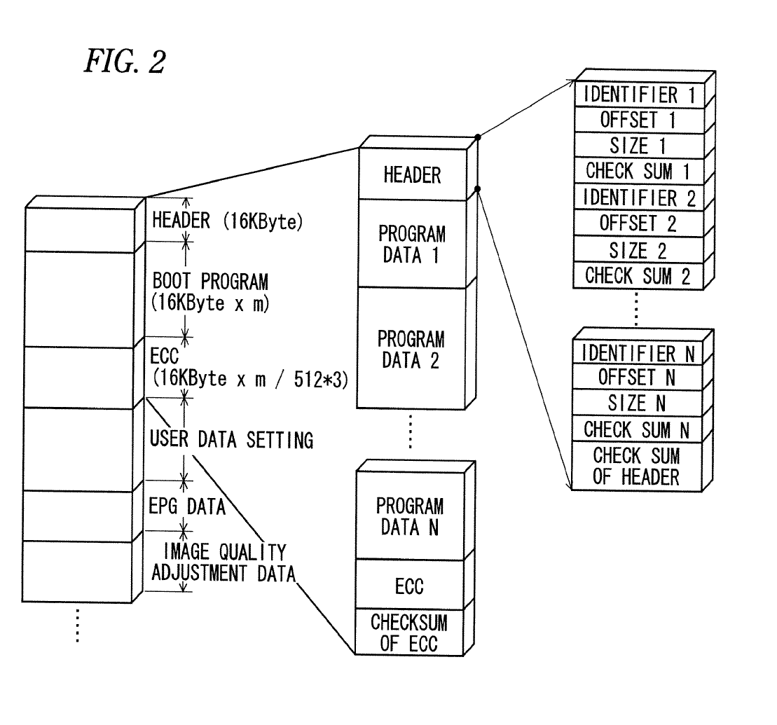

Hereinafter, an operation of the TV body 1 according to this embodiment is described. First, data to be written to the flash ROM 12 is described with reference to FIG. 2.

As illustrated in FIG. 2, the data to be written to the flash ROM 12 includes a header (16 Kbytes), a boot program (16 Kbytes×m), an ECC (16 Kbytes×m/512*3), and other data (user setting data, an electronic program guide (EPG) data, image quality adjustment data and the like).

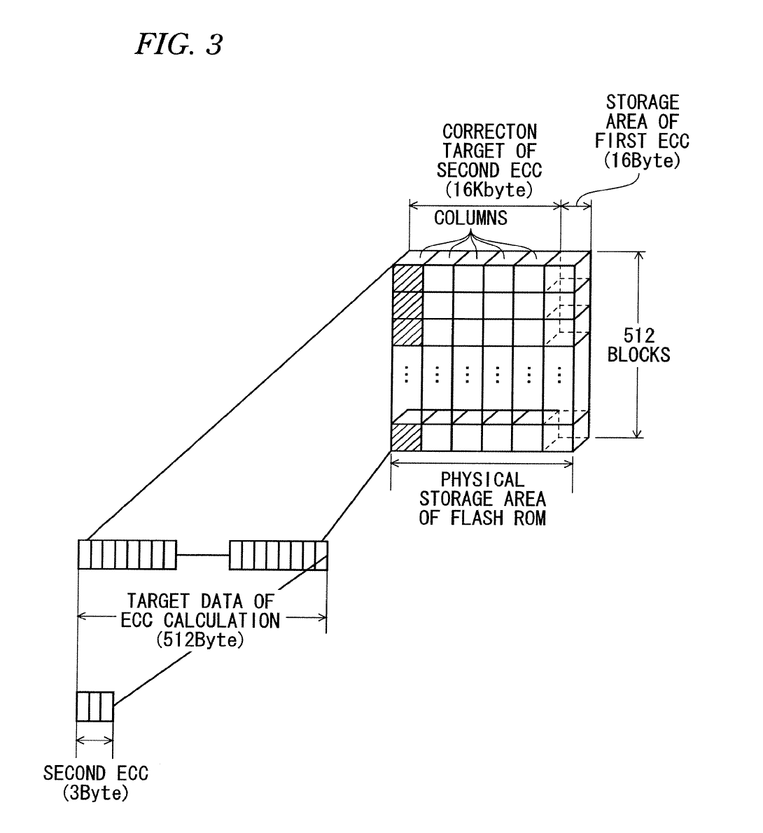

More specifically, data of the boot program is divided into a header, program data 1, program data 2 . . . program data n, an ECC, a check sum of the ECC, and the like. The header is that of the program. The ECC is a second ECC generated as described below with reference to FIG. 3.

Particularly, the header is subdivided into an identifier 1, an offset 1, a size 1, a check sum 1, an identifier 2, an offset 2, a size 2, a check sum 2, identifier N, an offset N, a size N, a check sum N, and a check sum of the header. The each offset m (m=1, 2 . . . N) indicates an offset thereto from the leading end of the data.

As illustrated in FIG. 3, usually, the physical storage area of the flash ROM 12 includes plural blocks (e.g., 512 blocks) partitioned every constant amount (e.g., about 16 Kbytes). This is a feature of the device serving as hardware. Each single partition of a block is referred to as a column.

That is, the flash ROM 12 includes a storage area (correction target of the second ECC correction) in which a predetermined number (512) of blocks are arranged, and a storage area (first ECC storage area) in which ECCs calculated respectively corresponding to the blocks are stored. Each block is configured by plural columns arranged in one direction (the row direction) as one unit, and the predetermined number (512) of blocks are arranged in a direction (the column direction) perpendicular thereto. An amount of data to be written at one time in the flash ROM 12 is hereinafter referred to as a “data set”. In the case of this example, the size of the first ECC storage area is 16 bytes.

In the TV apparatus, when a write target data set is written to the flash ROM 1, the MPU 20 extracts 1 byte at a predetermined column, e.g., a leading column from data to be stored in each block of the storage area of the flash ROM 12. The MPU 20 sets data of the size (i.e., 512 bytes) corresponding to the number of blocks as error correcting code (ECC) calculation target data. Then, the MPU 20 performs an error correction code calculation thereon. Thus, the MPU 20 generates an error correcting code of 3 bytes and gives the generated error correcting code to the data set. Then, the data set including an error correcting code of 3 bytes is written to the flash ROM 12.

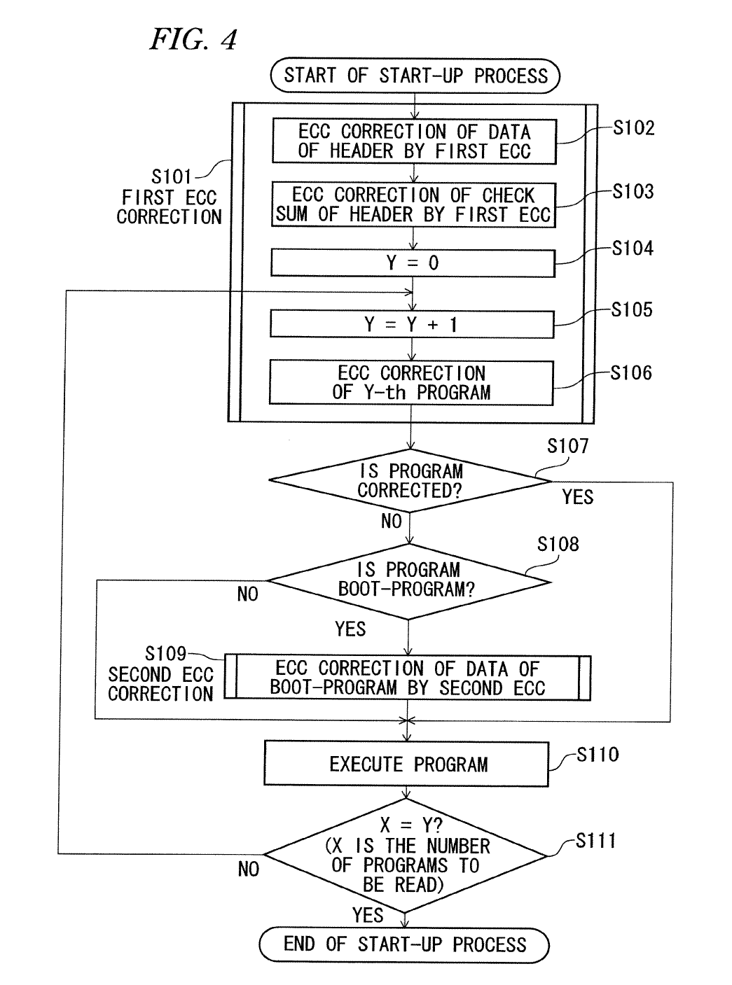

Hereinafter, a start-up process operation (information processing method) of the TV apparatus is described with reference to FIG. 4. It is assumed that the TV body 1 is connected to a commercial power supply such as a household wall plug via an AC chord or the like. In this state, when a power supply key of the key manipulation portion 14 of the TV body 1 or a power supply switch of the remote control 2 is turned on, electric power is supplied from the power unit 10 to each portion of the TV body 1 in the TV apparatus.

Then, in step S101 illustrated in FIG. 4, the MPU 20 executes a boot target program on the mask ROM 11 to perform error correction processing (first ECC correction) using the first ECC stored in the first ECC storage area.

In this case, first, in step S102, the MPU 20 loads the header of the program onto the DRAM 13 from the flash ROM 12. Then, the MPU 20 corrects the data of the header by performing ECC correction processing thereon.

Subsequently, in step S103, the MPU 20 verifies whether the check sum of the header is correct or erroneous, i.e., whether the check sum is correct. Then, the MPU 20 performs error correction on the check sum of the header.

After the error correction, in step S104, the MPU 20 sets the value Y of a counter to be “0”. In step S105, the MPU 20 increments (adds +1 to) the value Y of the counter. Then, the MPU 20 reads first program data from the flash ROM and loads the first program data onto the DRAM 13. In step S106, the MPU 20 performs error check and ECC correction on the first program data. If an error is corrected (Yes in step S107), the MPU 20 executes the program in step S110.

If the error cannot be corrected as a result of correcting the program data (No in step S107), in step S108, the MPU 20 checks whether the loaded program data represents a boot program. It is assumed that information obtained from the header can be used for the check.

If it is found that the program data represents a boot program (Yes in step S108), in step S109, the MPU 20 extracts the second ECC given to the program data and performs error correction processing (second ECC correction) on the program data using the second ECC.

In this processing, first, the MPU 20 verifies whether the check sum of the program data is correct or erroneous. If the check sum of the program data is incorrect, the MPU 20 performs ECC correction on the program data to correct the program data.

Then, in step S110, the MPU 20 executes the program corrected by the second ECC correction.

If it is found that the program data doesn't represent a boot program (No in step S108), in step S110, the MPU 20 executes the program regardless of whether the data is correct (without performing error correction and the like).

Then, the MPU 20 iteratively performs a loop from the above processing step S105 to a “No” of step S111 until the value Y of the counter reaches the number X of programs to be read. If the value Y of the counter reaches the number X of the programs to be read (Yes in step S111), the MPU 20 ends the start-up process.

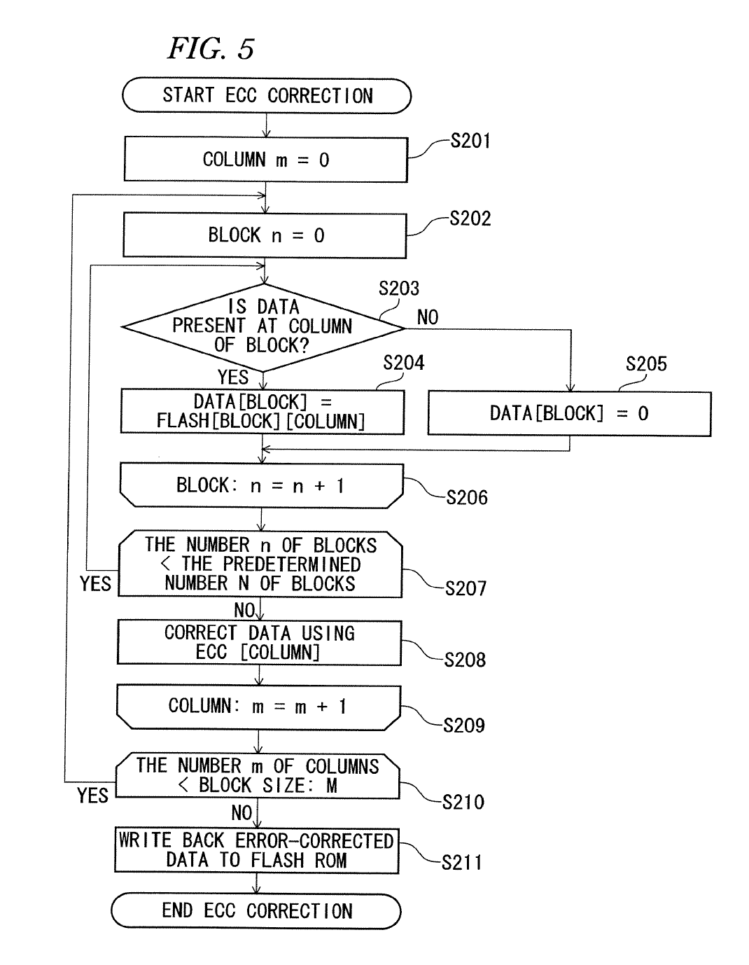

Next, the details of the above error correction processing to be performed in step S109 are described with reference to FIG. 5.

If error correction is performed, in step S201, the MPU 20 sets the number m of a column position counter to 0.

Subsequently, in step S202, the MPU 20 sets the number n of a block position counter (the number of blocks) to be 0. Thus, the MPU 20 initializes each of the position counters.

Next, in step S203, the MPU 20 determines whether data is present at the position of an m-th column of an n-th block.

Check source information is obtained from program length information stored in the header, and, whether data is present at the location of the m-th column of the n-th block is checked according to the check source information.

If data is present at this location (Yes in step S203), in step S204, the data (hereinafter represented by “flash[block][column]”), which is present at this location and corresponds the current block number (n), is set by the MPU 20 as the value of an element (hereinafter represented by “data[block]” (corresponding to the current block number)) of data which is to be checked with the second ECC corresponding to the current column and configured by such elements respectively corresponding to the blocks. That is, the MPU 20 sets data [block]=flash [block][column]. In addition, in step S206, the MPU 20 increments the block number (n). Data stored in the m-th column of the n-th block in the flash ROM 12 is represented as “flash [n][m]”.

If data is absent at the position (No in step S203), in step S205, the MPU 20 sets the element corresponding to the current block number such that data [block]=0. And, in step S206, the MPU 20 increments the block number n.

If the block number n is less than the predetermined number N of blocks (Yes in step S207), an operation to be performed in steps S203 to S206 is repeated.

If the block number n becomes equal to the predetermined number N of blocks (Yes in step S207), then, in step S208, the MPU 20 performs data correction using the ECC code data “ECC [column]” corresponding to the current column.

The expression “ECC [column]” is assumed to represent ECC code data for checking the data to be checked therewith corresponding to the current column.

In step S209, the column number m is incremented after the data correction. If the incremented column number m is less than a block size M (Yes in step S210), an operation to be performed in steps S202 to S209 is repeated.

If the column number m becomes equal to the block size M (Yes in step S210), next, in step S211, the error-corrected data is written back to the flash ROM 12.

Thus, according to the TV apparatus of this embodiment, when the boot program is read from the flash ROM 12 by the MPU 20 to the DRAM 13 upon powering up the TV body 1, normal error check (first ECC correction) is performed on the header of the data. If an erroneous part is detected in the block to which the program read from the flash ROM 12 is written, the data stored in the defective block is repaired into correct data by performing the error correction, using the second ECC included in the program data read from the flash ROM 12. The correct data obtained by repairing is written to the storage location corresponding to the erroneous part. Then, the correct data is read again therefrom. Thus, the boot program is correctly read and executed. Thus, the system (or each portion) of the TV body 1 can normally be booted. That is, even when a block to which a program is written is a defective one, a start-up operation can normally be performed.

That is, when data stored in the physical storage area on the flash ROM 12, to which a program important to an operation is written, is defective in units of, e.g., blocks, the second ECC is generated by extracting 1 byte from each source block, and given to the data. Thus, the program can be started.

The invention is not limited to the above embodiment, and can be embodied by changing the components thereof without departing from the substance in the implementation step. Each component described in the above embodiment can be implemented by a program installed in a storage device, such as a hard disk device, of a computer. Further, the functions according to the invention can be implemented by preliminarily storing the above program in a computer-readable medium and causing the computer to read the program from the medium. The medium include recording medium, e.g., a compact disc (CD)-ROM, a flash memory, removable medium and the like. Still further, the functions according to the invention can be implemented by decentrally arranging and storing the components in different computers connected via a network and providing the communication among the computers in each of which the associated component functions.

According to the embodiment, a program important to an operation can be read from a flash ROM and executed even when data stored in physical storage areas provided on the flash ROM are defective.

What is claimed is:

1. An information processing apparatus comprising:
a flash memory having a physical storage area configured to store data in a unit of a block, the block including a plurality of columns, the flash memory storing program data, the program data including
a program being stored in the physical storage area at a plurality of blocks, the program being provided to be executed upon a start-up of the apparatus,
a first error correcting code stored in the physical storage area inside the plurality of blocks, and
a second error correcting code stored in the physical storage area outside the plurality of blocks, the second error correcting code being provided separately from the program;
a first error correcting portion configured to perform, based on the first error correcting code, a first error correction on each block of the data to correct an erroneous part in each block; and
a second error correcting portion configured to perform, based on the second error correcting code, a second error correction on the erroneous part that remains uncorrected despite the first error correction.

2. The apparatus of claim 1, wherein the second error correcting code is generated by extracting one byte data from each of the plurality of blocks in the physical storage area in which the program is stored.

3. The apparatus of claim 1, wherein the second error correcting portion performs the second error correction to check and correct the erroneous part in the program.

4. The apparatus of claim 3, wherein the program is a boot program.

5. The apparatus of claim 3, further comprising:
a program executing portion configured to re-write the program in which the erroneous part is corrected by the second error correcting portion into the flash memory, and then, execute the program by reading out the re-written data from the flash memory to a dynamic random access memory.

6. An information processing method for processing data read data from a flash memory, the flash memory having a physical storage area configured to store a program within a plurality of blocks, the program to be executed at start-up of the apparatus, the method comprising:
performing, based on a first error correcting code, a first error correction on at least one of the plurality of blocks to correct an erroneous part in the at least one of the plurality of blocks, the first error correcting code stored in the physical storage area inside the plurality of blocks; and
performing, based on a second error correcting code, a second error correction on the erroneous part that remains uncorrected despite the first error correction.

7. An apparatus comprising:
a flash memory including a physical storage area configured to store data and program data, the program data comprises
a program being stored in a plurality of blocks of the physical storage area, the program being provided for execution at start-up of the apparatus,
a first error correcting code stored in the physical storage area inside at least one block of the plurality of blocks, and
a second error correcting code stored in one or more blocks of the plurality of blocks that are different from the at least one block of the plurality of blocks, the second error correcting code being provided separately from the program;
a first error correcting portion configured to perform, based on the first error correcting code, a first error correction on each block of the data stored in the physical storage area to correct an erroneous part in each block; and
a second error correcting portion configured to perform, based on the second error correcting code, a second error correction on the erroneous part that remains uncorrected despite the first error correction.

8. The apparatus of claim 7, wherein the second error correcting code is generated by extracting one or more bytes of data from each of the plurality of blocks in the physical storage area in which the program data is stored.

9. The apparatus of claim 7, wherein the second error correcting portion performs the second error correction to check and correct the erroneous part in the program data.

10. The apparatus of claim 9, wherein the program is a boot program.

11. The apparatus of claim 9, further comprising:
a program executing portion configured to re-write the program data in which the erroneous part is corrected by the second error correcting portion into the flash memory, and then, execute the program data by reading out the re-written data from the flash memory to a dynamic random access memory.
